(19) United States
(12) Patent Application Publication
(10) Pub. No.: US 2008/0258940 A1
(43) Pub. Date: Oct. 23, 2008

(54) APPARATUS AND METHOD FOR PREVENTING PASSWORD THEFT

(75) Inventors: LIN-KUN DING, Shenzhen (CN); SHIH-FANG WONG, Tu-Cheng (TW); XIANG-PING ZHOU, Shenzhen (CN); JIANG-FENG SHAN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/927,713

(22) Filed: Oct. 30, 2007

(30) Foreign Application Priority Data
Apr. 19, 2007 (CN) 200710200484.4

(51) Int. Cl. H03M 11/00

(52) U.S. Cl. 341/22

(57) ABSTRACT

An apparatus for protecting a password includes a keypad, a generator, and a processor. The keypad includes numeric keys for inputting a numeral and a display unit for displaying a random digit. The generator is coupled to the display unit for generating the random digit. The processor is configured for receiving the inputted numeral and calculating the password based on the inputted numeral and the random digit.

### BACKGROUND OF THE INVENTION

1. Field of the Invention

This invention relates to apparatuses and methods for preventing password theft and, more particularly, to an apparatus and method for preventing a password from being stolen when inputted via a keypad.

2. Description of Related Art

Generally, a method used to protect information is by the use of passwords. Thus, gaining access to the information can only be done by correctly inputting the passwords. However, using the passwords in public places, such as at automatic teller machines (ATM), the password may be observed, by others, when it is being entered in the ATMs.

Referring to FIG. 7, a traditional keypad 70 for inputting the password at a bank ATM is illustrated. The keypad 70 includes ten numeric keys 0˜9 for inputting numerals, a cancel key for canceling the transaction, and an enter key for entering the inputted numerals inputted numerals. The numeric keys are arranged in a predetermined manner for inputting the password conveniently. However, the predetermined manner of the numeric keys makes it is easy for a person with malicious intent to watch, decipher, and steal the password being entered.

One method to overcome the hard-coded keypad as mentioned above is to scramble the numbers on an LED lit numeric keypad. Referring to FIG. 8, the ten numeric keys of the keypad 80 have LED display devices disposed thereon. The numerals 0˜9 can be displayed on the ten numeric keys randomly by controlling the LED display devices. When the password is entered, for example, a six digits password, the arrangement of the ten numerals displayed on the keypad 80 can be reorganized six times. Thus making it harder for a person to steal the password as the arrangement of the ten numerals varies and harder to derive the numeric keys pressed when inputting the password.

However, displayed numerals may still be seen and the password can be stolen.

Therefore, a method and an apparatus for protecting the password from being illegally observed are desired.

### SUMMARY OF THE INVENTION

An apparatus for preventing a password from being stolen includes a keypad, a generator, and a processor. The keypad includes numeric keys for inputting numerals and a display unit for displaying a random digit. The generator is coupled to the display unit for generating the random digit. The processor is configured for receiving the inputted numerals and calculating the password based on the inputted numerals and the random digit.

A method for protecting a password includes: generating a random digit; displaying the random digit; receiving an inputted numeral that is corresponding to the random digit; and calculating the password based on the inputted numeral and the random digit.

A keypad for inputting a password includes a digit key area, a display unit, and an enter key. The digit key area is used for inputting ten numerals 0˜9 respectively. The display unit is used for displaying a random digit as a reference for a user to input a numeral via the digit key area. The enter key is used for entering inputted numerals.

Other advantages and novel features will become more apparent from the following detailed description of preferred embodiments when taken in conjunction with the accompanying drawings.

### BRIEF DESCRIPTION OF THE DRAWINGS

Many aspects of the apparatus and method can be better understood with reference to the following drawings. The components in the drawings are not necessarily to scale, the emphasis instead being placed upon clearly illustrating the principles of the present apparatus and method. Moreover, in the drawings, like reference numerals designate corresponding parts throughout the several views.

FIG. 1 is a schematic diagram illustrating a keypad in accordance with an exemplary embodiment, the keypad including a display unit;

FIG. 2 is a cross section view of the display unit of FIG. 1;

FIG. 3 is a block diagram of an apparatus for preventing password from being stolen in accordance with an exemplary embodiment;

FIG. 4 is the procedure of a method for preventing password from being stolen;

FIG. 5 is the procedure of a first embodiment of the method of FIG. 4; and

FIG. 6 is the procedure of a second embodiment of the method of FIG. 4.

### DETAILED DESCRIPTION OF THE INVENTION

Reference will now be made to the drawings to describe, in detail, preferred embodiments of a present apparatus and a method for preventing password theft.

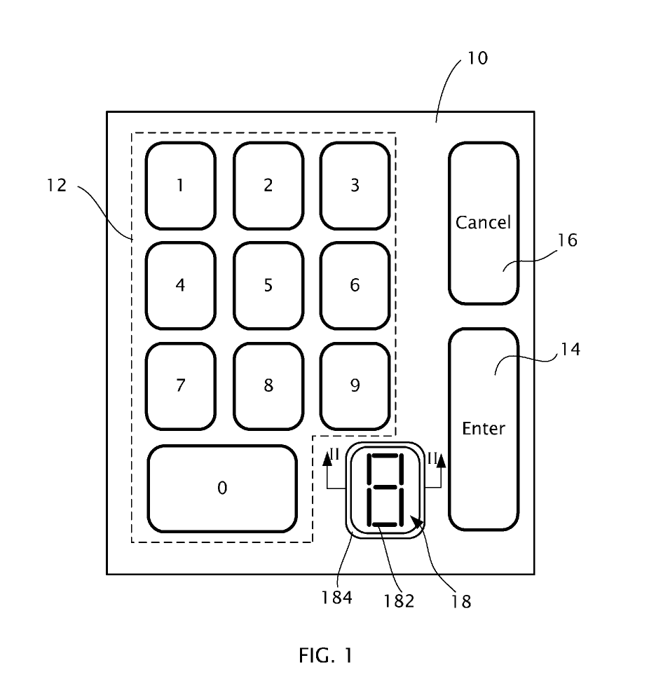

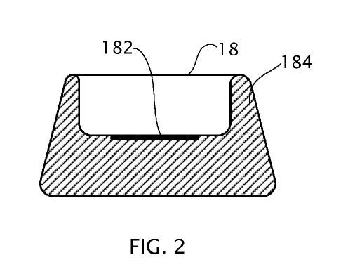

Referring to FIG. 1, a keypad 10 in accordance with an exemplary embodiment is illustrated. The keypad 10 is used for inputting inputted numerals via pressing input keys of the keypad 10. The keypad 10 includes a digit key area 12, an enter key 14, a cancel key 16, and a display unit 18.

The digit key area 12 includes ten digits 0˜9 correspondingly. The enter key 14 is used for predetermined functions such as confirming an entered input. The cancel key 16 is configured for canceling the entered input. The entered input can be the inputted numerals, an account number, an amount of money, etc.

The display unit 18 is used for displaying a random digit before inputting a part of the inputted numerals. The random digit is generated and ranges from 0˜9. The display unit 18 can be, for example, but not limited to, an LED based 7-segment display, a liquid crystal display, and an electrophoretic image display, etc. Referring also to FIG. 2, for exemplary purposes, the display unit 18 includes an LED based 7-segment display 182 and a security element 184. The security element 184 is used for preventing the random digit displayed on the LED based 7-segment display 182 to be exposed and viewable from sides of the display unit 18. That is, the random digit displayed on the LED based 7-segment display 182 is only viewable when viewed from the top of the display unit 18. The security element 184 is disposed around the LED based 7-segment display 182 and protrudes from four sides of the LED based 7-segment display 182. Thus, light emitted from the LED based 7-segment display 182 are blocked by the security element 184 and the displayed random digit cannot be viewed from the two sides of the display unit 18.

When a numeric password is to be entered, a corresponding random digit is displayed on the display unit 18, and the random digit is only viewable from the top of the display unit 18 as the security element 184 obstructs the random digit from being seen when attempting to view the random digit from the sides. A digit of the inputted numeral to be inputted is a sum of a corresponding digit of the numeric password and the corresponding random digit. For example, if the corresponding digit of the numeric password is 2, and the corresponding random digit is 3, thus the digit of the inputted numeral is the sum of 2 and 3, that is, 5. If the sum of the corresponding digit of the numeric password and the corresponding random digit is greater than 9; the digit of the inputted numeral to be entered would be the right most digit of the sum. For example, the digit of the numeric password is 6, and the corresponding random digit is 6, thus the digit of the inputted numeral to be inputted should be the right most digit of the sum of 6 and 6, that is, the digit of the inputted numeral is 2. Generally, the numeric password consists of more than one digit, for example, if a six digit numeric password is “256924”, and the random digits corresponding to each digit of the numeric password are “326911,” respectively, the inputted numerals to be inputted would be “572835”.

When the enter key 14 is pressed, the numeric password is decrypted based on inputted numerals and the corresponding random digits. The method of decrypting the numeric password is: if the inputted numeral is equal to or greater than the random digit, an individual digit of the numeric password is equal to the inputted numeral minus the random digit; if the inputted numeral is less than the random digit, the individual digit of the numeric password equals to ten plus the inputted numeral and then minus the random digit.

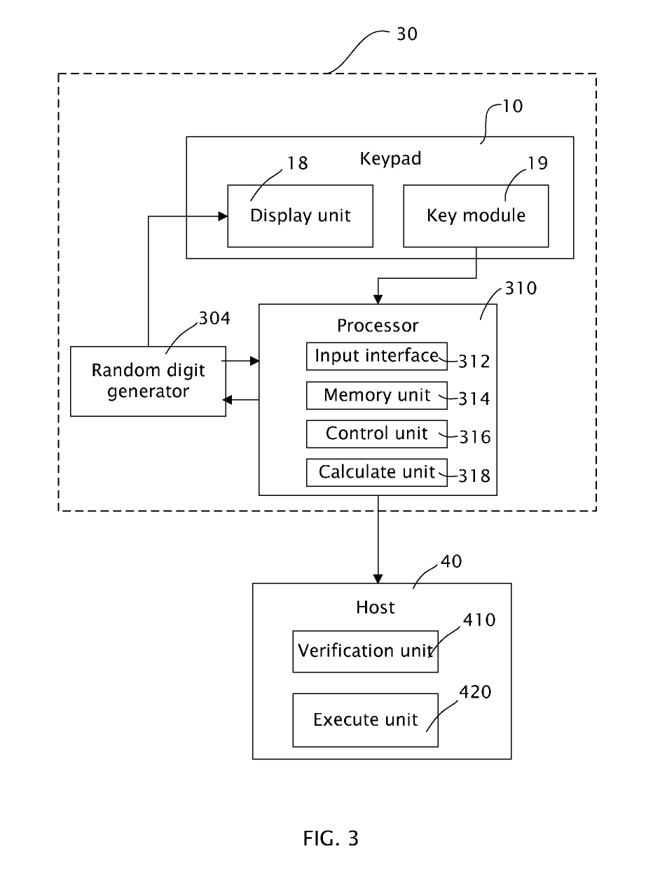

Referring to FIG. 3, a block diagram of an apparatus for preventing the password from being stolen is illustrated. The apparatus 30 is used for connecting to a host 40, for example, a personal computer, to input the password. The apparatus 30 includes the keypad 10, a processor 310, and a random digit generator 304 for generating the random digit.

The keypad 10 includes the display unit 18, a key module 19 for disposing the digit key area 12, the enter key 14, and the cancel key 16. The display unit 18 is coupled to the random digit generator 304 for displaying the random digit generated by the random digit generator 304. The key module 19 is connected to the processor 310 for inputting numbers.

The processor 310 is configured for receiving the numbers inputted by the user, controlling the random digit generator 304 to generate the random digits, and calculating the numeric password based on the inputted numerals and the random digits. The processor 310 includes an input interface 312, a memory unit 314, a control unit 316, and a calculate unit 318.

The input interface 312 is coupled to the key module 19 for receiving the numbers inputted via the key module 19. The memory unit 314 is used for storing the inputted numerals and the random digits generated by the random digit generator 304. The control unit 316 is configured for signaling the random digit generator 304 to generate the random digits in response to input actions on the key module 19. That is, after one digit key of the key module 19 is pressed, the control unit 316 signals the random digit generator 304 to generate another random digit. The calculate unit 318 is used for calculating the numeric password based on the inputted numerals and the random digits stored in the memory unit 314, wherein the calculating method is described above.

The host 40 includes a verification unit 410 and an execute unit 420. The verification unit 410 is coupled to the processor 310 for receiving the numeric password calculated by the calculate unit 318 and determining whether the password is valid. If the password is valid, the verification unit 410 signals the execute unit 420 to perform a predetermined function requested, for example, displaying the balance of the account. If the password is invalid, the verification unit 410 signals the execute unit 420 to display a password error prompt.

The apparatus 30 employs the display unit 18 to display the random digits, the inputted numerals have a relationship to the random digits and the numeric password. The numeric password can be decrypted based on the inputted numerals and the random digits. Each numeric digit of the numeric password does not have a constant relationship with the inputted numerals inputted nor with the locations of the input keys. Therefore, even if the inputted numerals or if the locations of the keys pressed is known, the numeric password is highly protected from password theft.

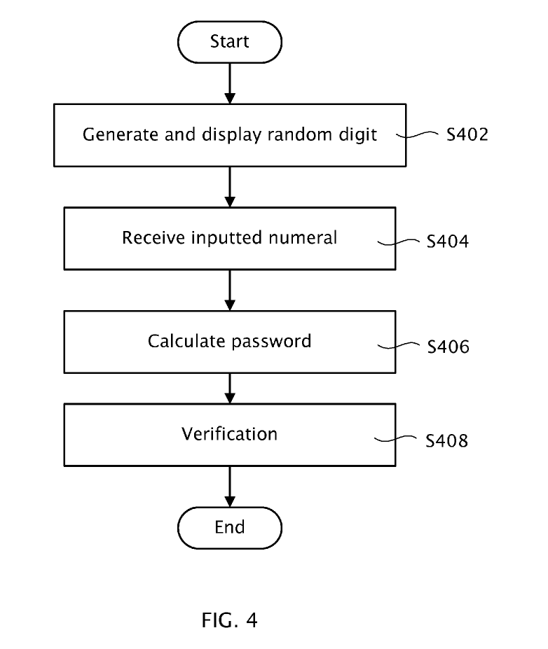

Referring to FIG. 4, a procedure of a method for preventing the password from being stolen is illustrated.

First, in step S402, the random digit generator 304 generates the random digits and transmits the random digits to the display unit 18 and the processor 310.

In step S404, the processor 310 receives the random digits and the inputted numerals inputted by the user via pressing the keys of the key pad 10.

In step S406, the processor 310 calculates the numeric password based on the received random digits and the inputted numerals, and transmits the numeric password to the host 40.

In step S408, the host 40 determines whether the numeric password is valid. If the numeric password is valid, the host 40 executes the predetermined task that the user requested, for example, displaying the balance of the account. If the password is invalid, the host 40 prompts the user that the password is invalid.

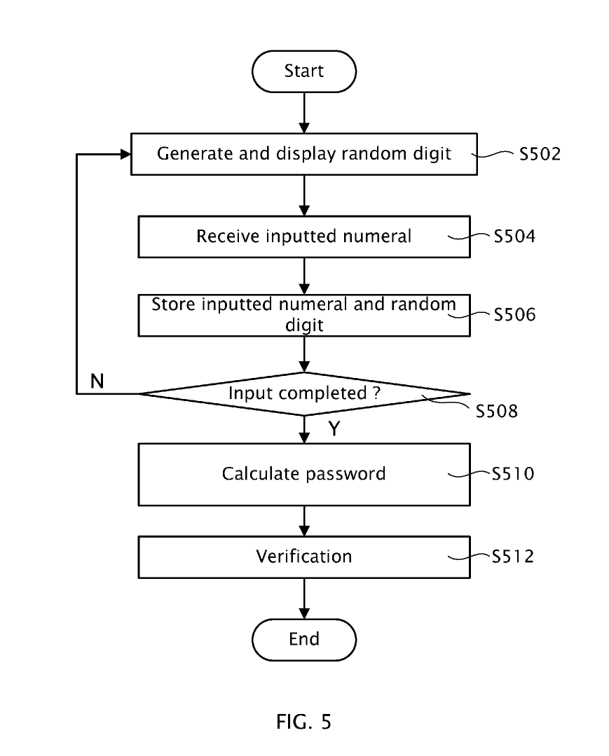

Generally, the numeric password is more than one digit, thus there are two ways to calculate the numeric password. Referring to FIG. 5, a first embodiment to calculate the numeric password is illustrated.

First, in step S502, the random digit generator 304 generates a random digit and transmits the random digit to the display unit 18 and the processor 310.

In step S504, the processor 310 receives the random digit and an inputted numeral inputted by the user. The inputted numeral corresponds to the random digit.

In step S506, the random digit and the inputted numeral are stored in the memory unit 314.

In step S508, the control unit 316 determines whether the enter key 14 is pressed. If the enter key 14 is not pressed, the procedure goes back to step 502 to generate and display another random digit for the user to input another inputted numeral. If the enter key 14 is pressed, the procedure proceeds to step 510.

In step S510, the processor 310 calculates the numeric password based on the stored random digits and the inputted numerals and transmits the numeric password to the host 40.

In step S512, the host 40 determines whether the numeric password is valid. If the numeric password is valid, the host 40 executes the predetermined task that the user requested, for example, displaying the balance of the account. If the numeric password is invalid, the host 40 prompts the user that the numeric password is invalid.

That is, the inputted numerals are stored in the memory unit 314 till all the inputted numerals are inputted completely according to the first embodiment. After all the inputted numerals are inputted completely, the processor 310 calculates the password based on the stored random digits and the inputted numerals.

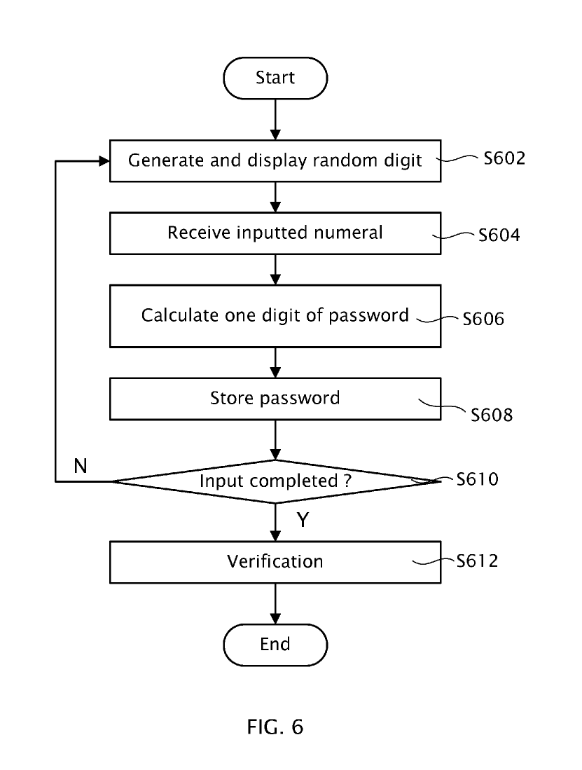

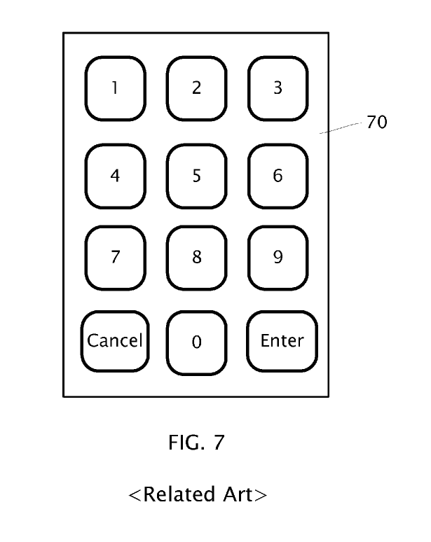

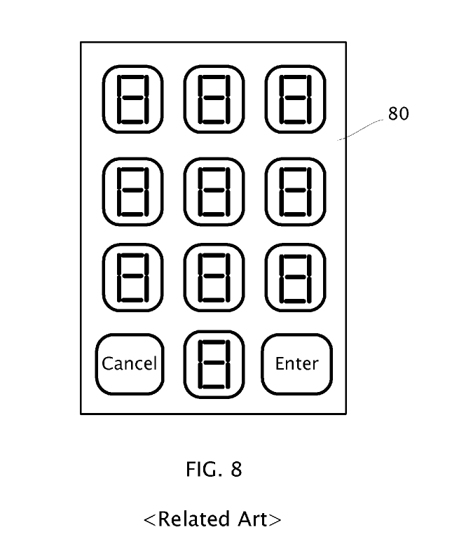

Referring to FIG. 6, a second embodiment to calculate the numeric password is illustrated.

First, in step S602, the random digit generator 304 generates a random digit and transmits the random digit to the display unit 18 and the processor 310.

In step S604, the processor 310 receives the random digit and an inputted numeral inputted by the user. The inputted numeral corresponds to the random digit.

In step S606, the processor 310 calculates one digit of the numeric password based on the random digit and the inputted numeral.

In step S608, the digit of the numeric password is stored in the memory unit 314.

In step S610, the control unit 316 determines whether the enter key 14 is pressed. If the enter key 14 is not pressed by the user, the procedure goes back to step 602 to generate and display another random digit for the user to input another inputted numeral. If the enter key 14 is pressed, the procedure proceeds to step 612.

In step S612, the host 40 determines whether the numeric password is valid. The numeric password consists of a plurality of digits in sequence stored in step S608. If the numeric password is valid, the host 40 executes the predetermined task that the user requested, for example, displaying the balance of the account. If the password is invalid, the host 40 prompts the user that the numeric password is invalid.

The method displays the random digits as references for the user to input inputted numerals, and the inputted numerals have a relationship to the random digits. The numeric password is calculated based on the inputted numerals and the random digits. Each numeric digit of the numeric password does not have a constant relationship with the inputted numerals inputted nor with the locations of the input keys. Therefore, even if the inputted numerals or if the locations of the keys pressed is known, the numeric password is highly protected from password theft.

The embodiments described herein are merely illustrative of the principles of the present invention. Other arrangements and advantages may be devised by those skilled in the art without departing from the spirit and scope of the present invention. Accordingly, the present invention should be deemed not to be limited to the above detailed description, but rather by the spirit and scope of the claims that follow, and their equivalents.

What is claimed is:

1. An apparatus for preventing a password from being stolen, comprising:
a keypad comprising numeric keys for inputting an inputted numeral and a display unit for displaying a random digit;
a generator coupled to the display unit for generating the random digit; and
a processor configured for receiving the inputted numeral and calculating the password based on the inputted numeral and the random digit.

2. The apparatus as claimed in claim 1, wherein the processor comprises an input interface for receiving the inputted numeral and the random digit.

3. The apparatus as claimed in claim 1, wherein the processor comprises a memory unit for storing the inputted numeral and the random digit.

4. The apparatus as claimed in claim 1, wherein the processor comprises a control unit for signaling the generator to generate the random digit in response to inputs from the key pad.

5. The apparatus as claimed in claim 1, wherein the processor comprises a calculate unit for calculating the password based on the inputted numeral and the random digit.

6. The apparatus as claimed in claim 5, wherein if the inputted numeral is equal to or greater than the random digit, the calculate unit calculates an individual digit of the password using the inputted numeral minus the random digit.

7. The apparatus as claimed in claim 5, wherein if the inputted numeral is less than the random digit, the calculate unit calculates an individual digit of the password using the inputted numeral plus ten then minus the random digit.

8. The apparatus as claimed in claim 1, wherein the display unit is selected from a group consisting of an LED based 7-segment display, a liquid crystal display, and an electrophoretic image display.

9. The apparatus as claimed in claim 1, wherein the generator changes the random digit after one of the numeric keys is pressed.

10. A method for preventing a password from being stolen, comprising:
generating a random digit;
displaying the random digit;
receiving an inputted numeral that is corresponding to the random digit; and
calculating the password based on the inputted numeral and the random digit.

11. The method as claimed in claim 10, further comprising: determining whether the password is valid.

12. The method as claimed in claim 10, further comprising: storing the random digit and the inputted numeral.

13. The method as claimed in claim 12, further comprising:
determining whether the inputted numeral is inputted completely;
waiting for receiving another inputted numeral and random digit if the inputted numeral is not inputted completely; and
calculating the password based on stored inputted numerals and random digits if the inputted numerals are inputted completely.

14. The method as claimed in claim 10, wherein the step of calculating the password comprises:
calculating one digit of the password based on the random digit and the inputted numeral; and
storing the digit of the password.

15. The method as claimed in claim 14, further comprising:
determining whether the inputted numeral is inputted completely;
waiting for receiving another inputted numeral and random digit if the inputted numeral is not inputted completely; and
sending stored password if the inputted numeral is inputted completely.

16. The method as claimed in claim 10, further comprising: changing the random digit after receiving the inputted numeral.

17. A keypad for inputting a password, comprising:
a digit key area for inputting ten numerals 0˜9 respectively;
a display unit for displaying a random digit as a reference for inputting an inputted numeral via the digit key area; and
an enter key for entering inputted numerals.

18. The keypad as claimed in claim 17, wherein the display unit is surrounded with protrusions.

19. The keypad as claimed in claim 17, wherein the display unit changes the random digit after inputting one inputted numeral via the digit key area.
